(19) United States
(12) Patent Application Publication
(10) Pub. No.: US 2026/0222095 A1
(43) Pub. Date: Jul. 30, 2026

(54) AUDIO CLOCK ADJUSTMENT FOR MULTI-CHANNEL AUDIO DATA OUTPUT IN NETWORK BASED PUBLIC ADDRESS

(71) Applicant: INTER-M CORPORATION, Yangju-si (KR)

(72) Inventors: Woo Geun LEE, Uijeongbu-si (KR); Jin Wook KIM, Gunpo-si (KR)

(73) Assignee: INTER-M CORPORATION, Yangju-si (KR)

(21) Appl. No.: 19/578,784

(22) Filed: Mar. 25, 2026

Related U.S. Application Data
(63) Continuation of application No. PCT/KR2024/014097, filed on Sep. 19, 2024.

(30) Foreign Application Priority Data
Sep. 26, 2023 (KR) 10-2023-0129529

(51) Int. Cl. H04H 20/47; G06F 9/448

(52) U.S. Cl. CPC H04H 20/47; G06F 9/4498

(57) ABSTRACT

There is disclosed a method for audio clock adjustment in network-based public address (PA). The disclosed method includes: generating an audio clock signal based on an occupancy level of an audio buffer in which digital audio data received through a network is buffered; and providing the digital audio data from the audio buffer in accordance with the generated audio clock signal, wherein generating the audio clock signal includes: when the occupancy level indicates that a first amount of the digital audio data remains in the audio buffer, generating, as the audio clock signal, a first audio clock signal from an oscillation clock signal; and when the occupancy level indicates that a second amount, different from the first amount, of the digital audio data remains in the audio buffer, setting, based on the occupancy level, a clock divisor and generating, as the audio clock signal, a second audio clock signal from a finite state machine (FSM) clock signal.

### CROSS-REFERENCE TO RELATED APPLICATIONS

This application is a continuation application of International Application No. PCT/KR2024/014097, filed Sep. 19, 2024, which claims the benefit of Korean Patent Application No. 10-2023-0129529, filed Sep. 26, 2023, in the Korean Intellectual Property Office, the disclosures of which are incorporated herein in their entirety by reference.

### FIELD

The present disclosure relates to audio clock adjustment in network-based public address (PA), and more particularly, relates to audio clock adjustment for multi-channel audio data output in network-based PA.

### BACKGROUND

A public address (PA) system is installed in an environment such as a building or a complex—for example, an apartment complex, a school, a government office, a large building, an airport, a shopping mall, or the like—and is configured to output sounds, such as announcement messages or background music, at a level or volume that can be heard by people over a wide area. Sometimes, this system also has a function of providing emergency broadcasting to notify of emergency situations, for example, a fire, an explosion, flooding, a power outage, an earthquake, or the like, occurring in or around the environment in which the system is installed. For such public address, various devices are installed in respective desired regions (e.g., branches of a company).

Recently, there have been numerous large-scale implementations of PA systems. In such an implementation, multiple regional facilities are connected via a network. In the PA system, latency may occur at its receiving side since audio data for PA may not be received at a uniform rate at the receiving side through the network.

In this regard, the Applicant has proposed, in Korean Patent No. 10-2400936, audio clock adjustment in network-based PA. The proposed scheme involves outputting audio data in accordance with an audio clock signal whose clock rate is adjusted based on how much digital audio data received through a network remains in an audio buffer, thereby suppressing an occurrence of latency while preventing loss of the audio data. The inventors have recognized that there is room to introduce several improved configurations to help implement such a scheme on hardware, for example, on a programmable logic device such as a field programmable gate array (FPGA) or on another type of logic circuitry, without excessive manufacturing cost.

### SUMMARY

Audio clock adjustment in network-based public address is disclosed herein.

In an example, a device for audio clock adjustment in network-based public address (PA) includes: an audio clock adjustment unit that generates an audio clock signal based on an occupancy level of an audio buffer in which digital audio data received through a network is buffered; and an audio data formatting unit that provides the digital audio data from the audio buffer in accordance with the generated audio clock signal, wherein generating the audio clock signal includes: when the occupancy level indicates that a first amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and when the occupancy level indicates that a second amount, different from the first amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.

The foregoing summary is provided to introduce, in a simplified form, a few aspects that are further described below in the Detailed Description. This summary is not intended to identify key or essential features of the claimed subject matter, nor is it intended to be used to delimit the scope of the claimed subject matter.

Furthermore, the claimed subject matter is not limited to implementations that provide any or all advantages discussed herein.

According to the present disclosure, by buffering audio data received through a network and then outputting the audio data in accordance with an audio clock signal having a variable clock rate, it is possible to prevent loss of the original audio data, such as discarding of data due to excessive buffering and insertion of data due to insufficient buffering, and also to suppress an occurrence of latency.

According to the present disclosure, a clock signal for outputting audio data may be generated in a cost-efficient manner with a less complex hardware design, even without a network switch supporting a protocol for delivery, such as Precision Time Protocol.

According to the present disclosure, in network-based PA, even when the number of channels carried in audio data is relatively large, and even when an FSM clock frequency available in underlying hardware for audio clock adjustment is limited, two adjacent ones of possible clock rates of the audio clock signal may not exhibit a sudden change in their difference, thereby allowing for suppression of excessively frequent switching between clock rates and of unsmooth audio playback.

### BRIEF DESCRIPTION OF THE DRAWINGS

FIG. 1 illustrates an example of audio communication for public address (PA) in a networked environment.

FIG. 2 is a block diagram illustrating an example of a network-based PA system in which the network-based PA receiver of FIG. 1 is implemented.

FIG. 3 is a block diagram illustrating an example of a local PA subsystem of FIG. 2.

FIG. 4 is a block diagram illustrating an example of the network-based PA receiver of FIG. 1.

FIG. 5 is a diagram illustrating an example of a finite state machine (FSM) running in an example operation of the audio clock adjustment unit of FIG. 4.

FIG. 6 is a diagram illustrating an example of a bit clock pulse generated by running of the FSM of FIG. 5.

FIG. 7 is a flowchart illustrating an example of a process for audio clock adjustment in network-based PA.

### DETAILED DESCRIPTION

Various terms used in the present disclosure are chosen from terminology for commonly used terms in view of their usage herein, which may be perceived differently depending on the perspective of a person skilled in the art, prior practice, or the emergence of new technology. In specific instances, some terms are ascribed their meanings as set forth in the detailed description. Accordingly, the terms used herein are to be defined consistently with their meanings in the context of the present disclosure, rather than simply by their names.

The terms “comprising,” “including,” “having,” etc. are used herein when specifying the presence of the elements listed thereafter, for example, certain features, numbers, steps, operations, constituent elements, information, or a combination thereof. Unless otherwise indicated, these terms and variations thereof are not meant to exclude the presence or addition of other elements.

As used herein, the terms “first,” “second,” and so forth are meant to identify several similar elements. Unless otherwise specified, such terms are not intended to impose limitations, for example, a particular order of these elements or of their use, but rather are used merely for referring to multiple elements separately. For instance, an element may be referred to in an example with the term “first” while the same element may be referred to in another example with a different ordinal number such as “second” or “third.” In such examples, these terms are not to limit the scope of the present disclosure. Also, the use of the term “and/or” in a list of multiple elements is inclusive of all possible combinations of the listed items, including any one or plurality of the items. Further, singular expressions include plural expressions unless expressly stated otherwise.

Certain examples of the present disclosure will now be described in detail with reference to the accompanying drawings. The present disclosure may, however, be embodied in many different forms and should not be construed as limited to the examples set forth herein; rather, these examples are given in order to provide a better understanding of the scope of the present disclosure.

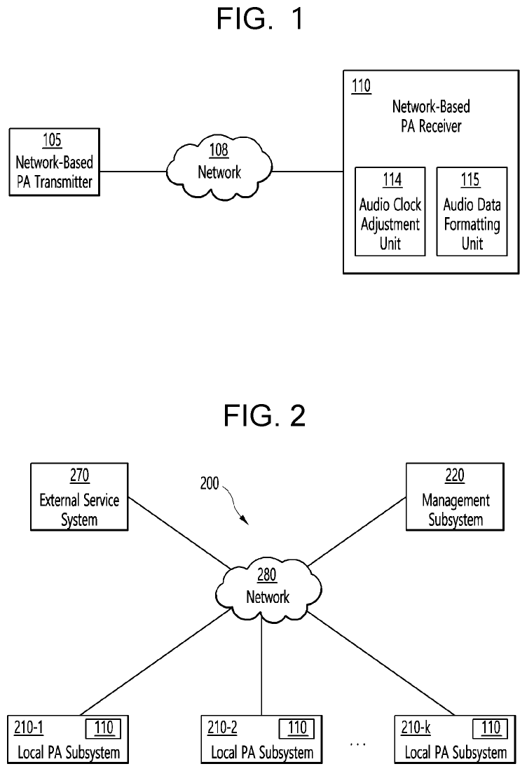

FIG. 1 illustrates an example of audio communication for public address (PA) in a networked environment.

In the illustrated example, a network-based PA transmitter 105 transmits audio data over a network 108 to a network-based PA receiver 110. In some example implementations, the network-based PA transmitter 105 may transmit digital audio data having a predetermined sample rate and a predetermined bit depth, in a predetermined data transmission manner, for example, a multicast manner, with a predetermined transmission period. The network-based PA receiver 110 may receive such digital audio data, for example, by joining a multicast group. In addition, the network-based PA receiver 110 may write the received audio data into a buffer (e.g., a First-In-First-Out (FIFO) buffer), read buffered audio data therefrom, and provide this audio data in accordance with a clock signal having a variably set clock rate. In this manner, even when, under a certain condition of the network 108, the audio data does not arrive at the network-based PA receiver 110 in accordance with the predetermined transmission period, the network-based PA receiver 110 may reduce latency that may occur at the network-based PA receiver 110.

By way of example, the network-based PA transmitter 105 may transmit more-than-two-channel audio data to the network-based PA receiver 110 through the network 108 once per predetermined transmission period of 1 ms. For example, the audio data may have, for each of its eight channels, a sample rate of 48 kHz and a bit depth of 24 bits and thus have an amount of ( 1/1000)×8×48×1000×24=9216 bits (i.e., 1152 bytes). The network-based PA receiver 110 may receive the eight-channel audio data and buffer the audio data in the buffer. For example, the network-based PA receiver 110 may periodically buffer the audio data in the buffer using a non-operating system (non-OS) design and thus without employing any device driver. When the audio data has accumulated to some extent in the buffer, the network-based PA receiver 110 may output the audio data in a predetermined internal interface format, for example, an eight-channel time-division multiplexing (TDM) interface format. In order to maintain, without large fluctuations, an amount of the audio data remaining in the buffer or a buffer occupancy level indicating the same, the network-based PA receiver 110 may adjust a rate of a clock signal for outputting the audio data. For example, the clock rate may be targeted at a reference rate and adjusted around the reference rate based on the current buffer occupancy level, where when the output audio data is provided, for example, at a 32-bit width, for each channel according to the eight-channel TDM interface format, the reference rate is determined, based on the 48 kHz sample rate of the per-channel audio data, as a bitrate of 8×48×1000×32=12.288×10⁶ bits per second, that is, 12.288 MHz.

To this end, as illustrated in FIG. 1, the network-based PA receiver 110 may be implemented to include an audio clock adjustment unit 114 and an audio data formatting unit 115, where the audio clock adjustment unit 114 generates an audio clock signal based on an occupancy level of an audio buffer in which digital audio data received through the network 108 is buffered, and the audio data formatting unit 115 provides the digital audio data from the audio buffer in accordance with the generated audio clock signal. The generation of the audio clock signal includes: when the occupancy level of the audio buffer indicates that a certain amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and when the occupancy level of the audio buffer indicates that another amount, different from the certain amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.

In a particular example, the network 108 may be an Internet Protocol (IP)-based network. In addition, the network-based PA transmitter 105 and the network-based PA receiver 110 may not involve a network switch that supports Precision Time Protocol (PTP), which is used for clock synchronization on the network 108, and thus the network 108 may be a non-PTP network.

FIG. 2 is a block diagram illustrating an example of a network-based PA system 200 in which the network-based PA receiver 110 is implemented. The network-based PA system 200 may provide PA throughout a target environment, for example, an indoor and/or outdoor environment of the following: a complex including multiple buildings; a collection of local offices distributed across multiple remote locations; at least a portion of a building; an architectural structure; or the like. For example, the target environment may be divided into a plurality of zones, and performing PA through the PA system 200 may include notifying the same or different messages across some zones. An example implementation of the network-based PA system 200 is discussed in further detail below.

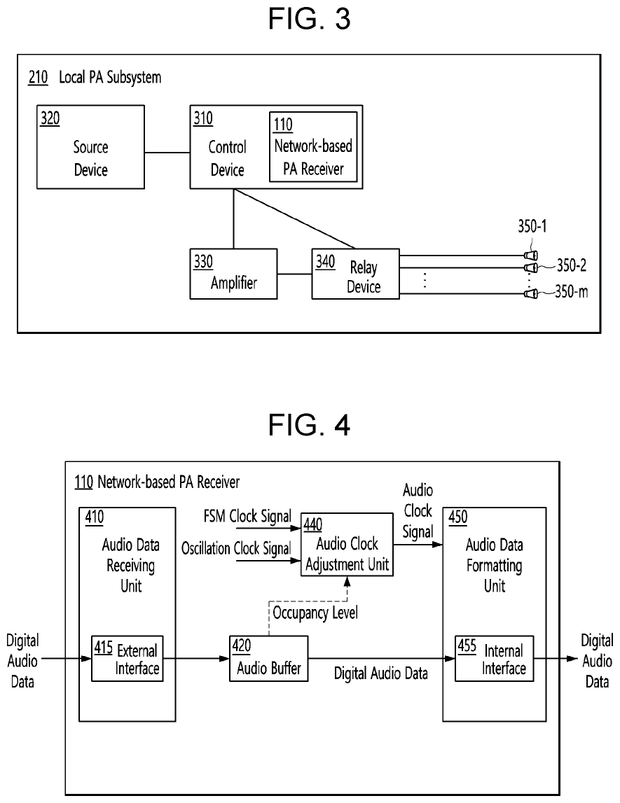

In the illustrated example, the network-based PA system 200 includes one or more local PA subsystems 210-1, 210-2, . . . , 210-k, which may be hereinafter individually or collectively referred to by the reference numeral “210.” For example, each local PA subsystem 210 may be constructed or installed in a corresponding zone within the target environment, for example, in a respective desired area or building, to enable PA in the corresponding zone. Referring to FIG. 3, an example implementation of each local PA subsystem 210 will be described below.

In the example of FIG. 2, a local PA subsystem 210 is communicatively coupled with an external entity (e.g., another local PA subsystem 210 of the network-based PA system 200) through a network 280. Examples of the network 280 include the Internet, a wide area network (WAN), a metropolitan area network (MAN), a local area network (LAN), or the like.

As illustrated in FIG. 2, the network-based PA system 200 may further include a management subsystem 220. The management subsystem 220 may be communicatively coupled with a local PA subsystem 210 through the network 280.

The management subsystem 220 may include a computing device operable to receive and process an input from a user (e.g., an administrator of the network-based PA system 200) and to provide an output representing some information. For example, a memory of the computing device may store program code that, when executed by a processor, provides a graphical user interface (GUI). The GUI may be displayed on a display device coupled to the computing device, and may include, for example, a control GUI that helps the user control at least a portion of the network-based PA system 200 (e.g., a particular device in one of the local PA subsystems 210-1, 210-2, . . . , 210-k of the network-based PA system 200), a schematic GUI that helps the user monitor at least a portion of the network-based PA system 200 (e.g., a particular device in one of the local PA subsystems 210-1, 210-2, . . . , 210-k of the network-based PA system 200), and/or another GUI.

Additionally, in some example implementations, a local PA subsystem 210 may be communicatively coupled with an external service system 270 through the network 280. For example, the external service system 270 may include a platform operated by a provider or operator of the network-based PA system 200 or by a third party. The platform may provide PA-related services, such as an audio streaming service, a PA state/flow monitoring service, a failover/remote monitoring service, a system management service, and/or another service, based on a cloud computing system, for example.

FIG. 3 is a block diagram illustrating an example of a local PA subsystem 210.

In the example of FIG. 3, the local PA subsystem 210 includes a control device 310, a source device 320, an amplifier 330, a relay device 340, and speakers 350-1, 350-2, . . . , 350-m, which may be hereinafter individually or collectively referred to by the reference numeral “350.”

In the illustrated example, the local PA subsystem 210 includes, among its components (e.g., the components 310, 320, 330, 340, and 350), a certain component that is communicatively coupled with another component in the local PA subsystem 210. Examples of such communication between the devices in the local PA subsystem 210 include communication via a network such as a LAN limited to a zone in which the local PA subsystem 210 is installed, digital serial communication, communication over a contact line, and various other types of analog or digital communication.

In the illustrated example, the local PA subsystem 210 includes, among its components (e.g., the components 310, 320, 330, 340, and 350), a certain component that is communicatively coupled, through the network 280, with an external entity, for example, another local PA subsystem 210 of the network-based PA system 200, which may be hereinafter referred to as the local PA subsystem 210′. Also, the components of the local PA subsystem 210′ may be hereinafter referred to in a similar manner. For example, a control device 310 and a source device 320 of the local PA subsystem 210′ may be referred to by the reference numerals “310′” and “320′,” respectively. In an example case where the control device 310 of the local PA subsystem 210 is capable of communication through the network 280, a certain other component in the local PA subsystem 210 may communicate with the local PA subsystem 210′ of the network-based PA system 200 (e.g., the control device 310′ of the local PA subsystem 210′) either through communication with the control device 310 or without going through the control device 310.

In the illustrated example, the local PA subsystem 210 is operable under control by the control device 310 of the local PA subsystem 210. To this end, the control device 310 may operate according to either internal control provided by the local PA subsystem 210 or external control provided to the local PA subsystem 210 (e.g., from the management subsystem 220 as illustrated in FIG. 2 or the computing device included therein), and may provide a control signal. For example, the control device 310 may provide the control signal based on a signal that is input to the control device 310 from a sensing device coupled to the control device 310, for example, a microphone, a camera, or another type of sensor, or from the local PA subsystem 210′ of the network-based PA system 200 or the management subsystem 220 (e.g., the computing device providing the control GUI in the management subsystem 220). For example, the control device 310 may use the input signal as the control signal or may generate and output the control signal based on the input signal. The control signal may be used to control the local PA subsystem 210 to which the control device 310 belongs (e.g., a particular device in the local PA subsystem 210), or may be provided to control the local PA subsystem 210′ of the network-based PA system 200 (e.g., a particular device in the local PA subsystem 210′).

In some example implementations, the control device 310 disposed in the local PA subsystem 210 may perform operations including: receiving an audio signal for PA from another device disposed in the local PA subsystem 210 (e.g., the source device 320) and/or through the network 280 from the local PA subsystem 210′ of the network-based PA system 200 (e.g., a particular device in the local PA subsystem 210′); providing the received audio signal to yet another device disposed in the local PA subsystem 210 (e.g., the amplifier 330, the relay device 340, or a certain type of additional device) and/or transmitting the received audio signal through the network 280 to the local PA subsystem 210′ of the network-based PA system 200 (e.g., a particular device in the local PA subsystem 210′); providing, to a certain device disposed in the local PA subsystem 210 (e.g., the relay device 340), a control signal that causes the audio signal to be delivered, for playback, to a particular speaker in the local PA subsystem 210 (e.g., at least a portion of the speakers 350-1, 350-2, . . . 350-m coupled to the relay device 340); and/or other operations.

In the illustrated example, the source device 320 is a device from which an audio signal in a certain format originates. For example, the source device 320 may include a sound player (e.g., a compact disc player (CDP), an MP3 player, an FM/AM radio tuner, an Internet streaming receiver, a cassette deck, or another sound player), a text-to-speech (TTS) synthesizer, a microphone (e.g., a remote microphone (RM)), or the like. As described above, the audio signal from the source device 320 of the local PA subsystem 210 may be provided to the control device 310 of the local PA subsystem 210 and may then also be provided, through the network 280, to the local PA subsystem 210′ (e.g., the control device 310′ of the local PA subsystem 210′).

In the illustrated example, the relay device 340 is connectable to a line (which may be referred to herein as an “audio line”) through which an audio signal having a given level (e.g., an amplifier-to-speaker level such as about 50 V to 100 V, or a line level such as about 1 V to 10 V) may be propagated. Accordingly, the relay device 340 may receive an audio signal through such an audio line. For example, the relay device 340 may receive as an input an audio signal provided from the control device 310. The audio signal may originate from inside (e.g., the source device 320) of the local PA subsystem 210 to which the relay device 340 belongs or from outside thereof (e.g., the source device 320′ in the local PA subsystem 210′ of the network-based PA system 200, the external service system 270, or the like). In some example implementations, the input audio signal of the relay device 340 may be an audio signal that is output from the control device 310, amplified through the intervening amplifier 330 between the relay device 340 and the control device 310, and then provided through a corresponding audio line to the relay device 340. For example, the control device 310 may output a line-level audio signal (e.g., about 1 V) to an audio line connected between the control device 310 and the amplifier 330, and the amplifier 330 may receive the audio signal output from the control device 310, amplify the audio signal to a speaker level (e.g., about 100 V), and output the amplified audio signal to an audio line connected between the amplifier 330 and the relay device 340. In some other example implementations, an output audio signal of the control device 310 may be provided to the relay device 340 through a corresponding audio line without going through the amplifier 330.

Further, in the illustrated example, the relay device 340 may relay a received audio signal to at least one of the speakers 350-1, 350-2, . . . , 350-m coupled to the relay device 340. Relaying of the audio signal to each speaker 350 may be enabled or disabled according to a control signal provided from the control device 310 to the relay device 340. For example, in response to receiving a particular control signal from the control device 310, the relay device 340 may enable or disable, in accordance with the received control signal, relaying of one of a plurality of input audio signals of the relay device 340 to at least one of the speakers 350-1, 350-2, . . . , 350-m coupled to the relay device 340. Then, when an input audio signal is relayed to a speaker 350, the speaker 350 may be driven to emit sound according to the audio signal.

In some example implementations, such audio signal relay control may be considered to involve on/off control of a contact corresponding to a channel between an input audio signal and a given speaker 350. For example, sixteen speakers corresponding to sixteen channels may be coupled to the relay device 340, where the relay device 340 may be provided with one or more input audio signals and may enable or disable, based on a control signal, relaying of one of the input audio signals to each of the sixteen speakers for playback. In other words, the relay device 340 may set a contact for each channel to be on or off according to the control signal. In this example, the relay device 340 may receive the control signal for the audio signal relay control from the control device 310 through a line connected between the control device 310 and the relay device 340, which may be, for example, a contact line that is separate from the audio line.

Referring to FIGS. 2 and 3, the network-based PA receiver 110 is illustrated as being disposed in a local PA subsystem 210 of the network-based PA system 200 and being included in the control device 310 of the local PA subsystem 210. In addition, although not illustrated, the network-based PA transmitter 105 may be disposed in the network-based PA system 200. For example, the network-based PA transmitter 105 may be included in the source device 320 of a particular one of the local PA subsystems 210-1, 210-2, . . . , 210-k.

FIG. 4 is a block diagram illustrating an example of the network-based PA receiver 110.

In the example of FIG. 4, the network-based PA receiver 110 includes an audio data receiving unit 410, an audio buffer 420, an audio clock adjustment unit 440, and an audio data formatting unit 450. The audio clock adjustment unit 440 and the audio data formatting unit 450 may be implemented as the audio clock adjustment unit 114 and the audio data formatting unit 115 of FIG. 1, respectively.

Other example implementations of the network-based PA receiver 110 are also contemplated. For example, the network-based PA receiver 110 may further include an additional component not illustrated and/or may include some but not all of the components listed with reference to FIG. 4.

In the illustrated example, the audio data receiving unit 410 includes an external interface 415. For example, the external interface 415 may be a modem, an Ethernet interface, a network interface card (NIC), or the like, and may receive digital audio data (e.g., eight-channel audio data samples) from the network-based PA transmitter 105 through a network (e.g., the network 280).

In the illustrated example, the received digital audio data is buffered in the audio buffer 420 for later retrieval. For example, the audio buffer 420 may be a circular First-In-First-Out (FIFO) buffer or another type of FIFO buffer.

In the illustrated example, the audio clock adjustment unit 440 generates a variable-rate audio clock signal having a variable clock rate based on an occupancy level indicating a current remaining amount of the digital audio data in the audio buffer 420. To this end, the audio clock adjustment unit 440 may use a finite state machine (FSM) clock signal generated to have a particular FSM clock frequency (e.g., 251.904 MHz) or an oscillation clock signal generated to have a particular oscillation frequency (e.g., 24.576 MHz). By way of example, the FSM clock signal may be generated by an FSM clock generation unit (not illustrated) implemented, together with the audio clock adjustment unit 440 and the audio data formatting unit 450, as logic on a programmable logic device (e.g., an FPGA) arranged in the network-based PA receiver 110 (e.g., from an output signal of an active oscillator or another type of oscillation circuit). Further, the oscillation clock signal may be generated, for example, by the oscillator or oscillation circuit or by a separate oscillator such as a crystal oscillator external to the programmable logic device.

Specifically, when the occupancy level of the audio buffer 420 indicates that a first amount of the digital audio data remains in the audio buffer 420, the audio clock adjustment unit 440 may generate, as the variable-rate audio clock signal, a first audio clock signal from the oscillation clock signal, and the first audio clock signal may have a particular clock rate less than or equal to the oscillation clock frequency. For example, the first audio clock signal may be a frequency-division signal of the oscillation clock signal.

Further, when the occupancy level of the audio buffer 420 indicates that a second amount, different from the first amount, of the digital audio data remains in the audio buffer 420, the audio clock adjustment unit 440 may set, based on the occupancy level, a clock divisor to be one of a plurality of integers that are greater than 1 and that are determined for a given sample rate of the digital audio data (e.g., a predefined sample rate such as 48 kHz, 44.1 kHz, 32 kHz, or 16 kHz), and may generate, as the variable-rate audio clock signal, a second audio clock signal from the FSM clock signal, the second audio clock signal having a different clock rate corresponding to the set clock divisor. In an example, the above-mentioned integers may be multiple (e.g., two) candidate divisors, each of which is an integer greater than 1. In this example, the candidate divisors depend on a reference rate and the FSM clock frequency, where the reference rate is based on the sample rate of the digital audio data. See, in particular, Tables 2 and 3 and related descriptions provided below.

Similarly, when the occupancy level of the audio buffer 420 indicates that a third amount, different from the first amount and the second amount, of the digital audio data remains in the audio buffer 420, the audio clock adjustment unit 440 may set the clock divisor to be a different one of the plurality of integers described above, and may generate, as the variable-rate audio clock signal, a third audio clock signal from the FSM clock signal, the third audio clock signal having a further clock rate corresponding to the clock divisor set to the different integer.

By way of example, the first amount of the digital audio data may be a value that falls within a numerical range indicating a “normal” buffer occupancy level, such as a range of values of an amount of audio data remaining in the audio buffer 420 such that the amount has a relatively small difference from a reference amount.

For example, this range may lie between a value of the reference amount minus a predetermined fraction (e.g., ⅕) of the reference amount and a value of the reference amount plus the fraction of the reference amount. Further, one of the second amount and the third amount of the digital audio data may be a value that falls within a numerical range indicating an “abnormally decreased” buffer occupancy level—that is, a range of values of an amount of audio data remaining in the audio buffer 420 such that the amount has a relatively large difference from the reference amount while being less than the reference amount. For example, this range may lie below a value of the reference amount minus the fraction of the reference amount. Still further, the other of the second amount and the third amount of the digital audio data may be a value that falls within a numerical range indicating an “abnormally increased” buffer occupancy level—that is, a range of values of an amount of audio data remaining in the audio buffer 420 such that the amount has a relatively large difference from the reference amount while being greater than or equal to the reference amount. For example, this range may lie above a value of the reference amount plus the fraction of the reference amount.

In some example implementations, the reference amount may be determined based on an amount of the digital audio data expected to be received by the audio data receiving unit 410 through the network. For example, as described above, when the network-based PA transmitter 105 transmits, with a predetermined transmission period of 1 ms, eight-channel audio data having, for each channel, a sample rate of 48 kHz and 24 sample bits, the network-based PA receiver 110 may aim to maintain, as much as possible, at least the following reference amount of audio data in the audio buffer 420 to prevent PA from being interrupted: an expected amount of audio data received per 1.5 ms (i.e., 1 ms plus a margin of 0.5 ms)—to be specific, (1.5/1000)×8×48×1000×24=13824 bits (i.e., 1728 bytes).

With regard to the design of the network-based PA receiver 110 and, in particular, of the audio clock adjustment unit 440, the following discussion addresses in detail: (i) how to determine the clock rate of the first audio clock signal, that is, the variable-rate audio clock signal generated from the oscillation clock signal, (ii) how to determine the FSM clock frequency, and (iii) how to determine the candidate divisors for use in setting the clock rate of the second or the third audio clock signal, that is, the variable-rate audio clock signal generated from the FSM clock signal. For the sake of convenient explanation, an example scenario is assumed in which the network-based PA receiver 110 has the oscillation clock frequency of 24.576 MHz and outputs eight-channel digital audio data having, for each channel, a 48 kHz sample rate and a 32-bit width, with the following ratio targeted at its maximum allowable value of 5%: a difference between two adjacent ones of possible clock rates of the variable-rate audio clock signal generated from the FSM clock signal, relative to the reference rate of 8×48×1000×32=12.288 MHz.

The clock rate of the audio clock signal generated from the oscillation clock signal may be the oscillation clock frequency or may be the oscillation clock frequency divided by a frequency-division factor greater than 1, and in particular, one of the following values that has the smallest difference from the reference rate: the oscillation clock frequency divided by J (where J=1, 2, . . . ). Thus, in the above-mentioned scenario, where the reference rate is 8×48×1000×32=12.288 MHz, this variable-rate audio clock signal may be generated from the oscillation clock signal such that the clock rate is 24.576/2=12.288 MHz.

The FSM clock frequency may be set to be less than or equal to a maximum clock frequency available on, for example, a programmable logic device on which several components such as the audio clock adjustment unit 440 and the audio data formatting unit 450 of the network-based PA receiver 110 are implemented. For example, when the maximum available clock frequency is 300 MHz, a candidate value of the FSM clock frequency may first be determined as 245.768 MHz, with some margin. It will be understood that a programmable logic device such as an FPGA typically increases, in unit price, in a nearly exponential manner as its maximum allowable clock frequency increases and accordingly, increasing the FSM clock frequency as desired is not cost-efficient, particularly when a required number of logic elements is not very large.

Now, a highest-priority candidate divisor may be found that is an integer satisfying the following condition: multiplying the reference rate of 12.288 MHz by the highest-priority candidate divisor results in a value closest to the candidate value of the FSM clock frequency. In this example, among various integer multiples of the reference rate, 12.288×20=245.760 MHz is closest to the candidate value of the FSM clock frequency (i.e., 245.768 MHz), and thus the highest-priority candidate divisor is 20. Table 1 shows three candidate divisors including the highest-priority candidate divisor and two adjacent integers and three corresponding possible clock rates.

TABLE 1

| | Clock rate (MHz) = | | Error rate (%) = |
|---|---|---|---|
| | FSM clock | Clock rate − | (clock rate − |
| Candidate | frequency/ | reference rate | reference rate)/ |
| divisor | candidate divisor | (MHz) | reference rate |
| 19 | 12.9352 | 0.6472 | 5.267% |
| 20 | 12.2884 | 0.0004 | 0.003% |
| 21 | 11.7032 | −0.5848 | −4.759% |

As can be seen from Table 1, a ratio of a difference between the two clock rates 12.9352 MHz and 12.2884 MHz respectively given for two candidate divisors 19 and 20 to the reference rate 12.288 MHz is equal to a difference between the two error rates 5.267% and 0.003% respectively given for the candidate divisors (i.e., 19 and 20). This error-rate difference is greater than the targeted ratio of 5%. In this regard, when the FSM clock frequency is limited as described above with the digital audio data carrying a large number of channels and thus the reference rate being high, it is noted that, as compared to what would otherwise be the case, a smaller integer is determined as a candidate divisor with a possible clock rate closer to the reference rate and a resulting difference between two error rates respectively given for two adjacent candidate divisors is greater.

In such a situation, the variable-rate audio clock signal may be generated by using the FSM clock signal without using the oscillation clock signal, while adjusting its clock rate so as to switch among the clock rates presented in Table 1.

However, the clock-rate switching may be excessively frequent due to the large error-rate difference. Thus, there may be a difficulty in smooth playback of audio data that is output in accordance with the audio clock signal.

On the other hand, using the FSM clock signal as mentioned with respect to Table 1 together with the above-described use of the oscillation clock signal may cause unnecessary switching between the following two nearly identical clock rates: the clock rate of the audio clock signal generated from the oscillation clock signal (i.e., 12.288 MHz) and the clock rate of the audio clock signal generated from the FSM clock signal (i.e., 12.2884 MHz).

Accordingly, the above-described candidate value 245.768 MHz may be used only to determine the highest-priority candidate divisor, and may not be used as the FSM clock frequency. Instead, the FSM clock frequency may be determined based on the reference rate of 12.288 MHz, the highest-priority candidate divisor (i.e., 20), and the targeted ratio of 5%. Then, based on the occupancy level of the audio buffer 420, switching may be performed between generating the variable-rate audio clock signal based on the FSM clock frequency and generating the variable-rate audio clock signal from the oscillation clock signal.

For example, the FSM clock frequency may be a product of the reference rate and a scaling factor, multiplied by the highest-priority candidate divisor or by a candidate divisor adjacent to the highest-priority candidate divisor, where the scaling factor is calculated from the targeted ratio. The scaling factor may be, for example, a value of 1 plus one-half of the targeted ratio or a value of 1 minus one-half of the targeted ratio.

Table 2 illustrates two candidate divisors and two corresponding possible clock rates in a case where the FSM clock frequency is determined as: (reference rate)×(1+(targeted ratio)/2)×(highest-priority candidate divisor)=12.288×(1+0.05/2)×20=251.904 MHz. A ratio of a difference between the two clock rates of Table 2 to the reference rate is lower than the targeted ratio of 5%.

TABLE 2

| | Clock rate (MHz) = | | Error rate (%) = |
|---|---|---|---|
| | FSM clock | Clock rate − | (clock rate − |
| Candidate | frequency/ | reference rate | reference rate)/ |
| divisor | candidate divisor | (MHz) | reference rate |
| 20 | 12.5952 | 0.3072 | 2.500% |
| 21 | 11.9954 | −0.2926 | −2.381% |

Then, when the occupancy level of the audio buffer 420 is “abnormally increased,” the audio clock adjustment unit 440 may operate in a “fast mode” in which the remaining data in the audio buffer 420 is read out faster by generating, from the FSM clock signal, the variable-rate audio clock signal to have a clock rate of 12.5952 MHz corresponding to the smaller candidate divisor (i.e., 20) in Table 2, that is, by generating an audio clock signal with a higher clock rate. Also, when the occupancy level of the audio buffer 420 is “abnormally decreased,” the audio clock adjustment unit 440 may operate in a “slow mode” in which the remaining data in the audio buffer 420 is read out more slowly by generating, from the FSM clock signal, the variable-rate audio clock signal to have a clock rate of 11.9954 MHz corresponding to the larger candidate divisor (i.e., 21) in Table 2. Meanwhile, when the occupancy level of the audio buffer 420 is “normal” (e.g., when it indicates that the first amount of the digital audio data remains in the audio buffer 420), the audio clock adjustment unit 440 may operate in a “normal mode” in which the remaining data in the audio buffer 420 is read out at a normal pace by generating, from the oscillation clock signal, the variable-rate audio clock signal to have a clock rate of 24.576/2=12.288 MHz, that is, by generating an audio clock signal having a clock rate that is between the two clock rates of Table 2 and that is spaced from the reference rate by a smaller interval than that for each of the two clock rates.

Table 3 illustrates two candidate divisors and two corresponding possible clock rates in a case where the FSM clock frequency is determined as: (reference rate)×(1−(targeted ratio)/2)×(highest-priority candidate divisor+1)=12.288×(1−0.05/2)×21=251.5968 MHz. A ratio of a difference between the two clock rates of Table 3 to the reference rate is lower than the targeted ratio of 5%.

TABLE 3

| | Clock rate (MHz) = | | Error rate (%) = |
|---|---|---|---|
| | FSM clock | Clock rate − | (clock rate − |
| Candidate | frequency/ | reference rate | reference rate)/ |
| divisor | candidate divisor | (MHz) | reference rate |
| 20 | 12.5798 | 0.2918 | 2.375% |
| 21 | 11.9808 | −0.3072 | −2.500% |

Then, when the occupancy level of the audio buffer 420 is “abnormally increased,” the audio clock adjustment unit 440 may operate in the “fast mode” by generating, from the FSM clock signal, the variable-rate audio clock signal to have a clock rate of 12.5798 MHz corresponding to the smaller candidate divisor (i.e., 20) in Table 3. Also, when the occupancy level of the audio buffer 420 is “abnormally decreased,” the audio clock adjustment unit 440 may operate in the “slow mode” by generating, from the FSM clock signal, the variable-rate audio clock signal to have a clock rate of 11.9808 MHz corresponding to the larger candidate divisor (i.e., 21) in Table 3. Meanwhile, when the occupancy level of the audio buffer 420 is “normal,” the audio clock adjustment unit 440 may operate in the “normal mode” by generating, from the oscillation clock signal, the variable-rate audio clock signal to have a clock rate of 24.576/2=12.288 MHz.

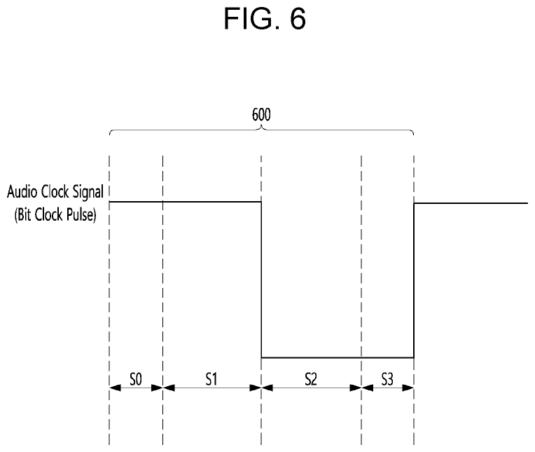

In some example implementations, the audio clock signal generated from the FSM clock signal by the audio clock adjustment unit 440 may include a bit clock pulse having a high-level portion and a low-level portion (e.g., one bit clock pulse 600 of the audio clock signal illustrated in FIG. 6). For example, a time width of the high-level portion of the audio clock signal may be a time width over which a first count number of successive pulses of the FSM clock signal extend, and a time width of the low-level portion of the audio clock signal may be a time width over which a second count number of successive pulses of the FSM clock signal extend, where the first count number plus the second count number is equal to the clock divisor that is set by the audio clock adjustment unit 440.

Additionally, at least one of the first count number and the second count number may be a greatest integer less than or equal to one-half of the clock divisor. For example, when the clock divisor N is even, both the first count number and the second count number may be N/2. When the clock divisor N is odd, the first count number may be [N/2]+1 and the second count number may be [N/2], or vice versa, where the symbol [x] indicates a greatest integer less than or equal to x. Then, a duty ratio of the audio clock signal may not deviate significantly from 50%. For example, in the cases of Tables 2 and 3, the candidate divisor whose value is 21 may cause a worst duty ratio, which is only 10/21 (i.e., about 47.6%).

In the example of FIG. 4, the audio data formatting unit 450 retrieves the digital audio data from the audio buffer 420 and provides the digital audio data through an internal interface 455 in accordance with the audio clock signal generated by the audio clock adjustment unit 440. In some example implementations, the internal interface 455 may be a TDM interface, another serial bus interface for audio data transmission, or another type of interface. The audio data formatting unit 450 may output the retrieved digital audio data in a particular format suitable for the internal interface 455 in accordance with the audio clock signal. For example, the audio data formatting unit 450 may format the retrieved digital audio data to conform to the internal interface 455 and may provide one bit of the formatted digital audio data per bit clock pulse of the audio clock signal.

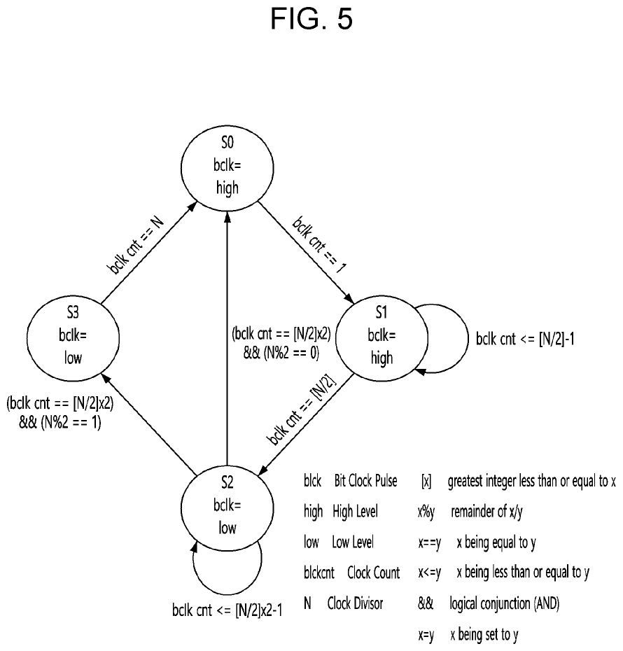

FIG. 5 is a diagram illustrating an example of an FSM 500 running in an example operation of the audio clock adjustment unit 440.

In the example of FIG. 5, in order to generate an audio clock signal from an FSM clock signal, the audio clock adjustment unit 440 runs the FSM 500 using the FSM clock signal and counts pulses of the FSM clock signal as a clock count while running the FSM 500. In this example, the FSM 500 has an initial state S0, a first state S1, a second state S2, and a third state S3.

In some example implementations, the FSM 500 may increment the clock count by 1 in response to detecting an edge (e.g., a rising edge of a pulse) of the FSM clock signal.

In the example of FIG. 5, the FSM 500 starts from the initial state S0. In the initial state S0, the clock count may be initialized to 0, and a maximum possible value of the clock count may be set to a clock divisor N that is set by the audio clock adjustment unit 440. Also, during the initial state S0, the audio clock signal may be generated to take a first binary level (e.g., a high level, as illustrated in FIG. 6).

In the illustrated example, the FSM 500 transitions from the initial state S0 to the first state S1 when the clock count is incremented to 1, for example, in response to a rising edge of the FSM clock signal. When the clock count is less than [N/2], the FSM 500 remains in the first state S1. During the first state S1, the audio clock signal may still be generated to take the first binary level (e.g., a high level, as illustrated in FIG. 6).

In the illustrated example, the FSM 500 transitions from the first state S1 to the second state S2 when the clock count reaches [N/2], for example, in response to additional ([N/2]−1) rising edges of the FSM clock signal. When the clock count is less than [N/2]×2, the FSM 500 remains in the second state S2. During the second state S2, the audio clock signal may be generated to take a second binary level (e.g., a low level, as illustrated in FIG. 6).

In the illustrated example, the FSM 500 transitions from the second state S2 when the clock count reaches [N/2]×2, for example, in response to additional [N/2] rising edges of the FSM clock signal. When the clock divisor N is even (that is, a remainder N %2 of N divided by 2 is 0) and the clock count is [N/2]×2, the FSM 500 transitions from the second state S2 to the initial state S0. When the clock divisor N is odd (that is, a remainder N %2 of N divided by 2 is 1) and the clock count is [N/2]×2, the FSM 500 transitions from the second state S2 to the third state S3. During the third state S3, the audio clock signal may still be generated to take the second binary level (e.g., a low level, as illustrated in FIG. 6). Thereafter, when the clock count reaches the clock divisor N, for example, in response to one additional rising edge of the FSM clock signal, the FSM 500 transitions from the third state S3 to the initial state S0.

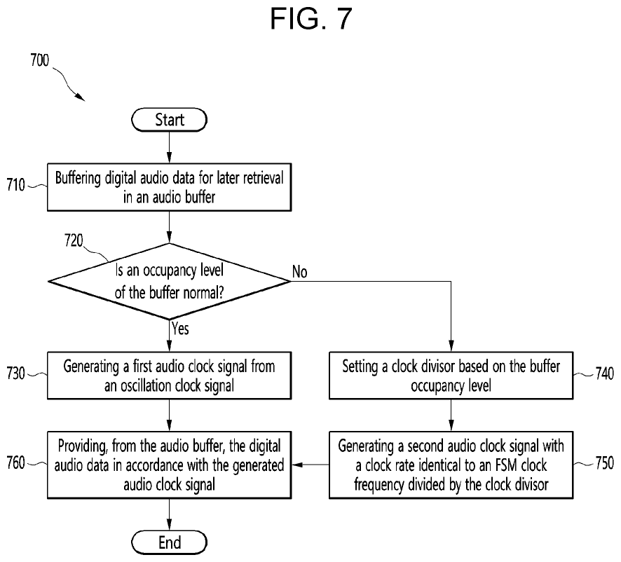

FIG. 7 is a flowchart illustrating an example of a process 700 for audio clock adjustment in network-based PA. For example, the process 700 may be performed by the network-based PA receiver 110 (e.g., the audio clock adjustment unit 440 and the audio data formatting unit 450). Other example flows of the process 700 are also contemplated. For example, the process 700 may include an additional operation not illustrated in FIG. 7, may include some but not all of the operations listed with reference to FIG. 7, and/or may be performed in an order different from that illustrated in FIG. 7.

In operation 710, digital audio data is buffered in an audio buffer for later retrieval. The digital audio data may be samples received through a network, for example, an IP-based non-PTP network.

In operation 720, it is determined whether an occupancy level indicating a current remaining amount of the digital audio data in the audio buffer is normal.

When it is determined that the occupancy level of the audio buffer is normal, in operation 730, a first audio clock signal is generated from an oscillation clock signal. The first audio clock signal may be a frequency-division signal of the oscillation clock signal.

When it is determined that the occupancy level of the audio buffer is not normal, in operation 740, a clock divisor is set, based on the occupancy level, to one of a plurality of candidate divisors that are integers greater than 1 and that are determined for a given sample rate of the digital audio data. The clock divisor may be set to a lower value when the occupancy level of the audio buffer is abnormally increased, and may be set to a higher value when the occupancy level of the audio buffer is abnormally decreased.

In operation 750, a second audio clock signal having a clock rate identical to an FSM clock frequency divided by the set clock divisor is generated from an FSM clock signal having the FSM clock frequency.

In some example implementations, the generation of the second audio clock signal may include running an FSM with the FSM clock signal and counting pulses of the FSM clock signal as a clock count during the running of the FSM. For example, the FSM may be characterized by the initial state S0, the first state S1, and the second state S2, which are mentioned above. Thus, when the clock count is initialized in the initial state S0 and then reaches 1, a transition may be made from the initial state S0 to the first state S1. The first state S1 may be maintained until the clock count reaches [N/2]. Thereafter, a transition may be made from the first state S1 to the second state S2. The second state S2 may be maintained until the clock count reaches [N/2]×2. The second audio clock signal may indicate a high level during the initial state S0 and the first state S1 and may indicate a low level during the second state S2. Further, when the clock divisor N is even and the clock count reaches [N/2]×2=N, a transition may be made from the second state S2 to the initial state S0. The FSM may also be characterized by the third state S3 such that, when the clock divisor N is odd and the clock count reaches [N/2]×2, a transition may be made from the second state S2 to the third state S3. During the third state S3, the second audio clock signal may indicate a low level. Thereafter, when the clock count reaches [N/2]×2+1=N, a transition may be made from the third state S3 to the initial state S0.

In operation 760, the digital audio data is retrieved from the audio buffer and is provided in accordance with the generated first or second audio clock signal. The retrieved digital audio data may be provided in a particular format (e.g., a format conforming to a TDM protocol) in synchronization with the audio clock signal.

The following are various examples pertaining to audio clock adjustment in network-based public address (PA).

In Example 1, a device for audio clock adjustment in network-based public address (PA) includes: an audio clock adjustment unit that generates an audio clock signal based on an occupancy level of an audio buffer in which the digital audio data received through a network is buffered; and an audio data formatting unit that provides the digital audio data from the audio buffer in accordance with the generated audio clock signal, wherein generating the audio clock signal includes: when the occupancy level indicates that a first amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and when the occupancy level indicates that a second amount, different from the first amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.

Example 2 includes the subject matter of Example 1, wherein the particular clock rate is the oscillation clock frequency divided by a frequency-division factor greater than 1.

Example 3 includes the subject matter of Example 1 or Example 2, wherein generating the audio clock signal further includes: when the occupancy level indicates that a third amount, different from the first amount and the second amount, of the digital audio data remains in the audio buffer, setting, based on the occupancy level, the clock divisor to an adjacent one of the plurality of integers, and generating, as the audio clock signal, a third audio clock signal from the FSM clock signal, the third audio clock signal having a further clock rate corresponding to the clock divisor set to the adjacent integer, wherein the particular clock rate is smaller than one of the different clock rate and the further clock rate and is greater than the other of the different clock rate and the further clock rate.

Example 4 includes the subject matter of Example 3, wherein the particular clock rate is spaced from a reference rate by a smaller interval than that for the different clock rate and than that for the further clock rate, and wherein the reference rate is determined, based on the given sample rate, as a targeted bitrate at which the digital audio data is to be provided from the audio buffer.

Example 5 includes the subject matter of Example 3 or Example 4, wherein the first amount of the digital audio data falls within a numerical range indicating a normal occupancy level of the audio buffer, wherein one of the second amount and the third amount of the digital audio data falls within a numerical range indicating an abnormally increased occupancy level of the audio buffer, and wherein the other of the second amount and the third amount of the digital audio data falls within a numerical range indicating an abnormally decreased occupancy level of the audio buffer.

Example 6 includes the subject matter of any one of Examples 1 to 5, wherein the audio buffer is a First-In-First-Out (FIFO) buffer.

Example 7 includes the subject matter of any one of Examples 1 to 6, wherein the clock divisor is further set based on a predetermined transmission period with which the digital audio data is transmitted to the device through the network.

Example 8 includes the subject matter of any one of Examples 1 to 7, wherein the device further includes an audio data receiving unit that receives the digital audio data through the network.

Example 9 includes the subject matter of any one of Examples 1 to 8, wherein the network is an Internet Protocol (IP)-based network.

Example 10 includes the subject matter of any one of Examples 1 to 9, wherein the network is a non-Precision Time Protocol (non-PTP) network.

Example 11 includes the subject matter of any one of Examples 1 to 10, wherein the generated second audio clock signal includes a bit clock pulse having a high-level portion and a low-level portion, wherein a time width of the high-level portion is a time width over which a first count number of successive pulses of the FSM clock signal extend, wherein a time width of the low-level portion is a time width over which a second count number of successive pulses of the FSM clock signal extend, and wherein the first count number plus the second count number is the clock divisor.

Example 12 includes the subject matter of Example 11, wherein at least one of the first count number and the second count number is a greatest integer less than or equal to one-half of the clock divisor.

Example 13 includes the subject matter of any one of Examples 1 to 12, wherein all of the plurality of integers are successive integers.

Example 14 includes the subject matter of any one of Examples 1 to 13, wherein the digital audio data is buffered in the audio buffer without using any device driver to control the buffering.

Example 15 includes the subject matter of any one of Examples 1 to 14, wherein the digital audio data is provided, by the audio data formatting unit, from the audio buffer in accordance with the generated audio clock signal through a more-than-two-channel time-division multiplexing (TDM) interface.

Example 16 includes the subject matter of any one of Examples 1 to 15, wherein the audio clock adjustment unit and the audio data formatting unit are implemented as logic on a programmable logic device.

Example 17 includes the subject matter of Example 16, wherein the audio clock adjustment unit receives, from an oscillator external to the programmable logic device, the oscillation clock signal to generate the first audio clock signal.

Example 18 includes the subject matter of Example 16 or Example 17, wherein the audio buffer is implemented in the programmable logic device or in a memory external to the programmable logic device.

In Example 19, a method for audio clock adjustment in network-based public address (PA) includes: generating an audio clock signal based on an occupancy level of an audio buffer in which the digital audio data received through a network is buffered; and providing the digital audio data from the audio buffer in accordance with the generated audio clock signal, wherein generating the audio clock signal includes: when the occupancy level indicates that a first amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and when the occupancy level indicates that a second amount, different from the first amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.

Example 20 includes the subject matter of Example 19, wherein the particular clock rate is the oscillation clock frequency divided by a frequency-division factor greater than 1.

Example 21 includes the subject matter of Example 19 or Example 20, wherein generating the audio clock signal further includes: when the occupancy level indicates that a third amount, different from the first amount and the second amount, of the digital audio data remains in the audio buffer, setting, based on the occupancy level, the clock divisor to an adjacent one of the plurality of integers, and generating, as the audio clock signal, a third audio clock signal from the FSM clock signal, the third audio clock signal having a further clock rate corresponding to the clock divisor set to the adjacent integer, wherein the particular clock rate is smaller than one of the different clock rate and the further clock rate and is greater than the other of the different clock rate and the further clock rate.

Example 22 includes the subject matter of Example 21, wherein the particular clock rate is spaced from a reference rate by a smaller interval than that for the different clock rate and than that for the further clock rate, and wherein the reference rate is determined, based on the given sample rate, as a targeted bitrate at which the digital audio data is to be provided from the audio buffer.

Example 23 includes the subject matter of Example 21 or Example 22, wherein the first amount of the digital audio data falls within a numerical range indicating a normal occupancy level of the audio buffer, wherein one of the second amount and the third amount of the digital audio data falls within a numerical range indicating an abnormally increased occupancy level of the audio buffer, and wherein the other of the second amount and the third amount of the digital audio data falls within a numerical range indicating an abnormally decreased occupancy level of the audio buffer.

Example 24 includes the subject matter of any one of Examples 19 to 23, wherein the audio buffer is a First-In-First-Out (FIFO) buffer.

Example 25 includes the subject matter of any one of Examples 19 to 24, wherein the clock divisor is further set based on a predetermined transmission period, and wherein the digital audio data is transmitted, with the predetermined transmission period, through the network to a device including the audio buffer and is buffered in the audio buffer.

Example 26 includes the subject matter of any one of Examples 19 to 25, wherein the method further includes receiving the digital audio data through the network.

Example 27 includes the subject matter of any one of Examples 19 to 26, wherein the network is an Internet Protocol (IP)-based network.

Example 28 includes the subject matter of any one of Examples 19 to 27, wherein the network is a non-Precision Time Protocol (non-PTP) network.

Example 29 includes the subject matter of any one of Examples 19 to 28, wherein the generated second audio clock signal includes a bit clock pulse having a high-level portion and a low-level portion, wherein a time width of the high-level portion is a time width over which a first count number of successive pulses of the FSM clock signal extend, wherein a time width of the low-level portion is a time width over which a second count number of successive pulses of the FSM clock signal extend, and wherein the first count number plus the second count number is the clock divisor.

Example 30 includes the subject matter of Example 29, wherein at least one of the first count number and the second count number is a greatest integer less than or equal to one-half of the clock divisor.

Example 31 includes the subject matter of any one of Examples 19 to 30, wherein all of the plurality of integers are successive integers.

Example 32 includes the subject matter of any one of Examples 19 to 31, wherein the digital audio data is buffered in the audio buffer without using any device driver to control the buffering.

Example 33 includes the subject matter of any one of Examples 19 to 32, wherein the digital audio data is provided from the audio buffer in accordance with the generated audio clock signal through a more-than-two-channel time-division multiplexing (TDM) interface.

Example 34 includes the subject matter of any one of Examples 19 to 33, wherein the method is performed by programmed logic in a programmable logic device.

Example 35 includes the subject matter of Example 34, wherein the method further includes receiving, from an oscillator external to the programmable logic device, the oscillation clock signal to generate the first audio clock signal.

Example 36 includes the subject matter of Example 34 or Example 35, wherein the audio buffer is implemented in the programmable logic device or in a memory external to the programmable logic device.

In Example 37, a computer-readable storage medium has stored therein computer-executable instructions, the computer-executable instructions, when executed by a computer processor, causing the computer processor to perform the method described in any one of Examples 19 to 36.

In Example 38, a computing device includes a processor and a computer-readable storage medium, wherein the computer-readable storage medium has stored therein computer-executable instructions that when executed by the processor, cause the computing device to perform the method described in any one of Examples 19 to 36.

In Example 39, a programmable logic device for audio clock adjustment in network-based public address (PA) includes programmable logic programmed to perform the method described in any one of Examples 19 to 36.

In Example 40, a network-based public address (PA) system includes a network-based PA receiver including the programmable logic device of Example 39.

In a particular example, an apparatus, device, system, machine, or the like mentioned herein may be any suitable type of computing device, may include such a computing device, or may be implemented in such a computing device. The computing device may include a processor and a computer-readable storage medium readable by the processor. The processor may execute one or more instructions stored in the computer-readable storage medium. The processor may also read other information stored in the computer-readable storage medium. In addition, the processor may store new information in the computer-readable storage medium and may update certain information stored in the computer-readable storage medium. The processor may include, for example, a central processing unit (CPU), a digital signal processor (DSP), a graphics processing unit (GPU), a processor core, a microprocessor, a microcontroller, a field-programmable gate array (FPGA), an application-specific integrated circuit (ASIC), other hardware and logic circuits, or any suitable combination thereof. The computer-readable storage medium is encoded with a variety of information, for example, a set of processor-executable instructions that may be executed by the processor, and/or other information. For example, the computer-readable storage medium may store computer program instructions that, when executed by the processor, cause a computing device (for example, the processor) to perform some operations disclosed herein, and/or information, data, variables, constants, data structures, or the like, for use in such operations. The computer-readable storage medium may include, for example, read-only memory (ROM), random-access memory (RAM), volatile memory, non-volatile memory, removable memory, non-removable memory, flash memory, solid-state memory, other types of memory devices, magnetic media such as a hard disk, a floppy disk, and a magnetic tape, optical recording media such as a CD-ROM and a DVD, magneto-optical media such as a floptical disk, other types of storage devices and storage media, or any suitable combination thereof.

In a particular example, operations, techniques, processes, or any aspect or portion thereof described herein may be embodied in a computer program product. Such a computer program may be implemented in any type of programming language (e.g., compiled or interpreted) that is executable by a computer, for example, assembly, machine language, a procedural language, an object-oriented language, or the like, and may be combined with a hardware implementation. The computer program product may be distributed in a form of a computer-readable storage medium or may be distributed online. For online distribution, some or all of the computer program product may be temporarily stored in a server (e.g., in a computer-readable storage medium of the server) or may be temporarily generated.

The foregoing description has been presented to illustrate and describe some examples in detail. It will be understood by those skilled in the art that many modifications and variations are possible in light of the above teachings without departing from the scope of the present disclosure. In various examples, suitable results may be achieved even if the above-described techniques are performed in a different order, and/or if some of the components of the above-described systems, architectures, devices, circuits, and the like are coupled or combined in a different manner, or substituted for or replaced by other components or equivalents thereof.

Therefore, the scope of the present disclosure is not to be limited to the precise form disclosed, but rather defined by the following claims and equivalents thereof.

What is claimed is:

1. A device for audio clock adjustment in network-based public address (PA), comprising:
an audio clock adjustment unit that generates an audio clock signal based on an occupancy level of an audio buffer in which digital audio data received through a network is buffered; and
an audio data formatting unit that provides the digital audio data from the audio buffer in accordance with the generated audio clock signal,
wherein generating the audio clock signal comprises:
when the occupancy level indicates that a first amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and
when the occupancy level indicates that a second amount, different from the first amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.

2. The device of claim 1, wherein the particular clock rate is the oscillation clock frequency divided by a frequency-division factor greater than 1.

3. The device of claim 1, wherein generating the audio clock signal further comprises:
when the occupancy level indicates that a third amount, different from the first amount and the second amount, of the digital audio data remains in the audio buffer, setting, based on the occupancy level, the clock divisor to an adjacent one of the plurality of integers, and generating, as the audio clock signal, a third audio clock signal from the FSM clock signal, the third audio clock signal having a further clock rate corresponding to the clock divisor set to the adjacent integer,
wherein the particular clock rate is smaller than one of the different clock rate and the further clock rate and is greater than the other of the different clock rate and the further clock rate.

4. The device of claim 1, wherein the digital audio data is provided, by the audio data formatting unit, from the audio buffer through a more-than-two-channel time-division multiplexing (TDM) interface in accordance with the generated audio clock signal.

5. The device of claim 1, wherein the audio clock adjustment unit and the audio data formatting unit are implemented as logic on a programmable logic device, and wherein the audio clock adjustment unit receives, from an oscillator external to the programmable logic device, the oscillation clock signal to generate the first audio clock signal.

6. A method for audio clock adjustment in network-based public address (PA), comprising:
generating an audio clock signal based on an occupancy level of an audio buffer in which digital audio data received through a network is buffered, and
providing the digital audio data from the audio buffer in accordance with the generated audio clock signal,
wherein generating the audio clock signal comprises:
when the occupancy level indicates that a first amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and
when the occupancy level indicates that a second amount, different from the first amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.

7. The method of claim 6, wherein the particular clock rate is the oscillation clock frequency divided by a frequency-division factor greater than 1.

8. The method of claim 6, wherein generating the audio clock signal further comprises:
when the occupancy level indicates that a third amount, different from the first amount and the second amount, of the digital audio data remains in the audio buffer, setting, based on the occupancy level, the clock divisor to an adjacent one of the plurality of integers, and generating, as the audio clock signal, a third audio clock signal from the FSM clock signal, the third audio clock signal having a further clock rate corresponding to the clock divisor set to the adjacent integer,
wherein the particular clock rate is smaller than one of the different clock rate and the further clock rate and is greater than the other of the different clock rate and the further clock rate.

9. The method of claim 6, wherein providing the digital audio data comprises providing the digital audio data from the audio buffer through a more-than-two-channel time-division multiplexing (TDM) interface in accordance with the generated audio clock signal.

10. A programmable logic device for audio clock adjustment in network-based public address (PA), comprising programmable logic programmed to perform:
generating an audio clock signal based on an occupancy level of an audio buffer in which digital audio data received through a network is buffered; and
providing the digital audio data from the audio buffer in accordance with the generated audio clock signal,
wherein generating the audio clock signal comprises:
when the occupancy level indicates that a first amount of the digital audio data remains in the audio buffer, generating, as the audio clock signal, a first audio clock signal from an oscillation clock signal having an oscillation clock frequency, the first audio clock signal having a particular clock rate less than or equal to the oscillation clock frequency; and
when the occupancy level indicates that a second amount, different from the first amount, of the digital audio data remains in the audio buffer, setting, based on the occupancy level, a clock divisor to be one of a plurality of integers that are greater than 1 and that are determined for a given sample rate of the digital audio data, and generating, as the audio clock signal, a second audio clock signal from a finite state machine (FSM) clock signal having an FSM clock frequency, the second audio clock signal having a different clock rate corresponding to the set clock divisor.
